(19) United States
(12) Patent Application Publication
(10) Pub. No.: US 2025/0267822 A1
(43) Pub. Date: Aug. 21, 2025

(54) Thermally Conductive Device

(71) Applicant: Polytronics Technology Corp., HSINCHU (TW)

(72) Inventors: PIN HSUAN LI, Hsinchu (TW); Jie Yu, Kunshan City (CN); YI-HSUAN LEE, Taichung City (TW); TUNG-CHENG TSAI, Taoyuan City (TW); YI-AN SHA, XINDIAN CITY (TW)

(21) Appl. No.: 18/668,690

(22) Filed: May 20, 2024

(30) Foreign Application Priority Data
Feb. 19, 2024 (TW) 113105789

(51) Int. Cl. H05K 7/20

(52) U.S. Cl. CPC H05K 7/20518

(57) ABSTRACT

A thermally conductive device includes an electrically insulating but thermally conductive layer, a first thermally conductive lead frame, and a second thermally conductive lead frame. The electrically insulating but thermally conductive layer has a top surface, a bottom surface, and a sidewall therebetween. The first thermally conductive lead frame has a top metal plate, a first extending part, and a second extending part. The top metal plate is disposed on the top surface. The first extending part horizontally extends from the top metal plate and goes beyond the sidewall. The second extending part extends from the first extending part and goes beyond the bottom surface. The second thermally conductive lead frame has a bottom metal plate and a third extending part. The bottom metal plate is disposed on the bottom surface. The third extending part extends downward from the bottom metal plate.

### BACKGROUND OF THE INVENTION

### (1) Field of the Invention

The present application relates to a thermally conductive device, and more specifically, to a thermally conductive device having a lead frame structure for thermal conduction.

### (2) Description of the Related Art

It is well-known that electronic products generate heat during operation, and their performance is compromised once the accumulation of heat reaches a certain threshold. Therefore, substrates (e.g., PCB) in electronic products often include additional thermally conductive devices, or alternatively, the substrates are directly replaced with thermally conductive boards having excellent heat-conductive characteristics. Regarding the thermally conductive devices, please refer to a thermally conductive device 100 in FIG. 1, which shows its front view.

In FIG. 1, the thermally conductive device 100 includes an electrode 10, an electrode 12, and an electrically insulating but thermally conductive layer 11 laminated therebetween. The electrode 10 and the electrode 12 are made of metal, while the electrically insulating but thermally conductive layer 11 is made of a ceramic material, by which the electrode 10 is electrically isolated from the electrode 12. On a substrate, one pad to be welded is disposed on a region adjacent to a heat-generating device (e.g., a power device or other active/passive devices requiring cooling), while the other pad to be welded is disposed on a region away from the heat-generating device. The electrode 10 is welded to the pad adjacent to the heat-generating device, and the electrode 12 is welded to the pad away from the heat-generating device. Because the thermally conductive device 100 is superior to the substrate in thermal conduction, heat prioritizes the thermally conductive device 100 as its thermally conductive path. In this way, the heat from the heat-generating device can be rapidly conducted from the electrode 10 to the electrode 12 to reduce the accumulation of heat.

However, numerous issues arise from this type of structural design that places the electrodes on the right and left sides. For example, the electrode 10 is quite far from the electrode 12. This structural design stretches the distance between the electrode 10 and the electrode 12, consequently reducing the amount of heat conducted from the electrode 10 to the electrode 12. In addition, both the electrode 10 and the electrode 12 exhibit better thermal conductivity than that of the electrically insulating but thermally conductive layer 11 in thermal conduction, and therefore the transfer efficiency of heat is compromised due to the excessive length of the electrically insulating but thermally conductive layer 11.

Second, the contact area between the electrode 10 (or the electrode 12) and the electrically insulating but thermally conductive layer 11 is small. It is understood that the amount of heat received is positively correlated with the cross-sectional area perpendicular to the heat flow direction. If the contact area is small, the amount of heat to be conducted is also small, and vice versa. Moreover, due to the poor conductive efficiency of the conventional device 100, a significant amount of solder is required to cover both the electrode 10 and the electrode 12 to enhance thermal conduction. Conventionally, the solder covers the bottoms of the electrode 10 and the electrode 12, and then climbs upwards along their sides. The thermally conductive capability of the thermally conductive device is significantly affected by the usage amount of the solder. However, the usage amount of solder is difficult to be precisely controlled, causing inconsistencies in performance during mass production.

Accordingly, there is a need to improve the structural design so as to address the issues of the thermally conductive device 100 as described above.

### SUMMARY OF THE INVENTION

The present invention provides a thermally conductive device having a lead frame structure for thermal conduction. More specifically, the thermally conductive device of the present invention includes an electrically insulating but thermally conductive layer, and at least two thermally conductive lead frames (e.g., a first thermally conductive lead frame and a second thermally conductive lead frame hereinafter). The first thermally conductive lead frame has a metal plate and a lead extended from the metal plate. The first thermally conductive lead frame attaches to the top surface of the electrically insulating but thermally conductive layer through the metal plate, and its lead bends and extends downward. Similarly, the second thermally conductive lead frame has a metal plate and a lead extended from the metal plate. The second thermally conductive lead frame attaches to the bottom surface of the electrically insulating but thermally conductive layer through the metal plate, and its lead bends and extends downward, by which the lead of the second thermally conductive lead frame and the lead of the first thermally conductive lead frame are on the same side. This design enlarges the cross-sectional area perpendicular to the heat flow direction while decreasing the thickness of the electrically insulating but thermally conductive layer, effectively shortening the conductive path. The structure of the present invention significantly improves the efficiency of thermal conduction, eliminating the need for using as much solder as usual.

In accordance with an aspect of the present invention, a thermally conductive device includes an electrically insulating but thermally conductive layer, a first thermally conductive lead frame, and a second thermally conductive lead frame. The electrically insulating but thermally conductive layer has a top surface, a bottom surface, and a sidewall. The top surface is opposite to the bottom surface, and the sidewall connects to the top surface and the bottom surface. The first thermally conductive lead frame has a top metal plate, a first extending part, and a second extending part. The top metal plate is disposed on the top surface. The first extending part is parallel to the electrically insulating but thermally conductive layer, and extends from the top metal plate and extends beyond the sidewall. The second extending part extends from the first extending part and extends beyond the bottom surface. The second thermally conductive lead frame has a bottom metal plate and a third extending part. The bottom metal plate is disposed on the bottom surface. The third extending part extends from the bottom metal plate and extends in a direction away from the electrically insulating but thermally conductive layer.

In an embodiment, the electrically insulating but thermally conductive layer has a length. The first extending part extends beyond the sidewall by a first distance. If the sum of the length and the first distance are calculated as 100%, the first distance ranges from 19% to 51%.

In an embodiment, the first thermally conductive lead frame further includes a first connecting terminal connected to the second extending part, and the second thermally conductive lead frame further includes a second connecting terminal connected to the third extending part. The first connecting terminal extends parallel to the bottom metal plate toward the second connecting terminal, and the second connecting terminal extends parallel to the bottom metal plate toward the first connecting terminal.

In an embodiment, the first connecting terminal has a first bottom surface, and the second connecting terminal has a second bottom surface. The first bottom surface and the second bottom surface are on the same horizontal plane. The second extending part extends beyond the bottom metal plate by a second distance, and the bottom metal plate is spaced apart from the horizontal plane by a third distance. If the third distance is calculated as 100%, the second distance ranges from 35% to 80%.

In an embodiment, the first thermally conductive lead frame further includes a first connecting terminal connected to the second extending part, and the second thermally conductive lead frame further includes a second connecting terminal connected to the third extending part. The first connecting terminal and the second connecting terminal extend toward each other. The first connecting terminal has a first bottom surface, and the second connecting terminal has a second bottom surface. The first bottom surface and the second bottom surface are on the same horizontal plane. An angle is formed between the first bottom surface of the first connecting terminal and the horizontal plane, and the angle is less than 30 degrees.

In an embodiment, an angle is formed between the second bottom surface of the second connecting terminal and the horizontal plane, and the angle is less than 30 degrees.

In an embodiment, the thermally conductive device further includes a first sputtering layer and a second sputtering layer. The first sputtering layer covers the top surface of the electrically insulating but thermally conductive layer, and the second sputtering layer covers the first sputtering layer.

In an embodiment, the first sputtering layer has a first lattice constant, and the electrically insulating but thermally conductive layer has a second lattice constant. A ratio of the first lattice constant to the second lattice constant ranges from 0.9 to 1.2.

In an embodiment, a ratio of a thickness of the first sputtering layer to a thickness of the second sputtering layer is in a range from 1:1 to 1:4.

In an embodiment, the thermally conductive device further includes a first electroplating layer and a second electroplating layer. The first electroplating layer covers the second sputtering layer, and the second electroplating layer covers the first electroplating layer, by which the second electroplating layer is able to be securely connected to the top metal plate through solder.

In an embodiment, a ratio of a thickness of the first electroplating layer to a thickness of the second electroplating layer is in a range from 1:2 to 1:4.

In an embodiment, the thermally conductive device further includes a packaging layer. The packaging layer entirely covers the top metal plate, the electrically insulating but thermally conductive layer, and the bottom metal plate. The packaging layer partially covers the first extending part and the third extending part.

In an embodiment, the first thermally conductive lead frame further includes a first connecting terminal connected to the second extending part, and the second thermally conductive lead frame further includes a second connecting terminal connected to the third extending part, wherein the first connecting terminal and the second connecting terminal extend toward each other. The first connecting terminal of the first thermally conductive lead frame physically contacts the packaging layer, and the second connecting terminal of the second thermally conductive lead frame physically contacts the packaging layer.

In an embodiment, the first extending part of the first thermally conductive lead frame has a first corner and a second corner. The first extending part extends to the first corner in a direction parallel to the electrically insulating but thermally conductive layer, extends from the first corner to the second corner in a direction parallel to the sidewall, and then extends from the second corner in a direction away from the sidewall, thereby connecting to the second extending part. The third extending part of the second thermally conductive lead frame has a third corner, a fourth corner, and a fifth corner. The third extending part extends to the third corner in a direction parallel to the electrically insulating but thermally conductive layer, extends from the third corner to the fourth corner in a direction parallel to the sidewall, extends from the fourth corner to the fifth corner in a direction away from the sidewall, and then extends from the fifth corner in a direction parallel to the sidewall, thereby extending away from the electrically insulating but thermally conductive layer.

In an embodiment, the thermally conductive device further includes a packaging layer. The packaging layer entirely covers the top metal plate, the electrically insulating but thermally conductive layer, and the bottom metal plate. The packaging layer partially covers the first extending part and the third extending part.

In an embodiment, the first thermally conductive lead frame further includes a first connecting terminal connected to the second extending part, and the second thermally conductive lead frame further includes a second connecting terminal connected to the third extending part, wherein the first connecting terminal and the second connecting terminal extend toward each other. The first connecting terminal of the first thermally conductive lead frame physically contacts the packaging layer, and the second connecting terminal of the second thermally conductive lead frame physically contacts the packaging layer.

In an embodiment, a thickness of the first thermally conductive lead frame ranges from 0.1 mm to 0.25 mm.

In an embodiment, the thermally conductive device includes a plurality of the first thermally conductive lead frames and a plurality of the second thermally conductive lead frames.

In an embodiment, the first thermally conductive lead frame and the second thermally conductive lead frame are made of copper or copper alloy.

In an embodiment, the thermally conductive device further includes an adhesive layer disposed between the electrically insulating but thermally conductive layer and the first thermally conductive lead frame. The adhesive layer is made of a material selected from the group consisting of epoxy resin, silicone, acrylic resin, polyurethane, and a mixture or copolymer of combinations thereof.

In an embodiment, the electrically insulating but thermally conductive layer is made of epoxy resin and a thermally conductive filler. The thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof.

In an embodiment, the electrically insulating but thermally conductive layer is made of a ceramic material. The ceramic material is selected from the group consisting of zirconium nitride, boron nitride, aluminum nitride, silicon nitride, aluminum oxide, magnesium oxide, zinc oxide, silicon dioxide, titanium dioxide, and any combination thereof.

In an embodiment, a roughness (Ra) of the top surface and the bottom surface of the electrically insulating but thermally conductive layer ranges from 0.01 μm to 10 μm.

### BRIEF DESCRIPTION OF THE DRAWINGS

The present application will be described according to the appended drawings in which:

FIG. 1 shows a front view of a conventional thermally conductive device;

FIG. 2 shows a three-dimensional view of a thermally conductive device of the present invention;

FIG. 3 shows a cross-sectional view of the thermally conductive device along the line AA depicted in FIG. 2;

FIG. 4 shows an embodiment of the thermally conductive device depicted in FIG. 3;

FIG. 5 shows another embodiment of the thermally conductive device depicted in FIG. 3;

FIG. 6A shows a cross-sectional view of a thermally conductive device of the present invention after packaging;

FIG. 6B shows the cross-sectional view of the thermally conductive device depicted in FIG. 6A after punching; and

FIG. 7 to FIG. 9 show three-dimensional views of a thermally conductive device of the present invention.

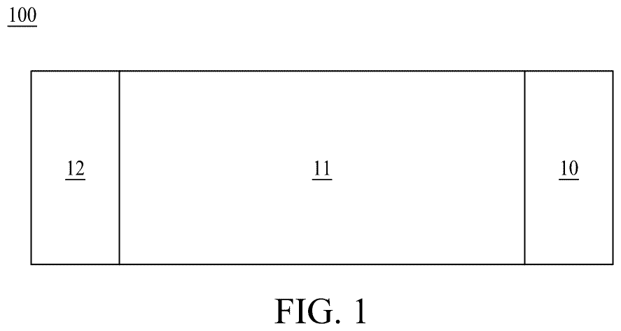

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

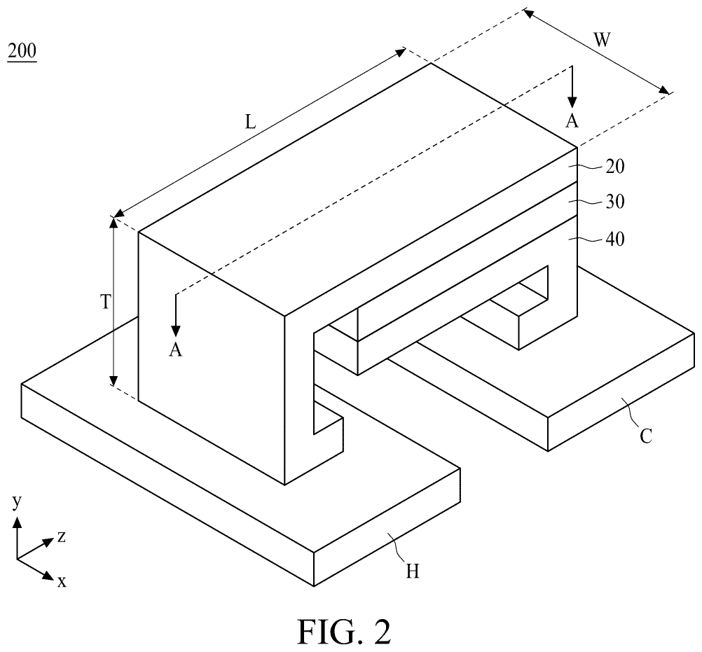

Please refer to FIG. 2, which presents a three-dimensional view of a thermally conductive device 200 of the present invention. For clarity, FIG. 2 illustrates the x-axis, y-axis, and z-axis to show the orientation in space. The thermally conductive device 200 includes a first thermally conductive lead frame 20, an electrically insulating but thermally conductive layer 30, and a second thermally conductive lead frame 40. The first thermally conductive lead frame 20 and the second thermally conductive lead frame 40 are made of copper or copper alloy. For example, copper foils can be punched into small pieces with structures identical to those of the first thermally conductive lead frame 20 and the second thermally conductive lead frame 40 as shown in FIG. 2. Subsequently, the first thermally conductive lead frame 20 and the second thermally conductive lead frame 40 are assembled onto the electrically insulating but thermally conductive layer 30 for each thermally conductive device 200. In this manner, the first thermally conductive lead frame 20 attaches to the top of the electrically insulating but thermally conductive layer 30, with a bent lead extending downward. The second thermally conductive lead frame 40 attaches to the bottom of the electrically insulating but thermally conductive layer 30, also with a bent lead extending downward. The lead of the first thermally conductive lead frame 20 and the lead of the second thermally conductive lead frame 40 can be welded to different regions, thereby facilitating the conduction of heat from one region to the other one. The electrically insulating but thermally conductive layer 30 is laminated between the first thermally conductive lead frame 20 and the second thermally conductive lead frame 40, thereby electrically isolating the first thermally conductive lead frame 20 from the second thermally conductive lead frame 40 and preventing arcing. The electrically insulating but thermally conductive layer 30 may be made of a composite material or a ceramic material. In an embodiment, the electrically insulating but thermally conductive layer 30 is made of epoxy resin and a thermally conductive filler (i.e., made of the composite material as previously mentioned), and the thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof. In an embodiment, in order to enhance the adhesion between the composite material and metal, the thermally conductive device 200 further includes an adhesive layer disposed between the electrically insulating but thermally conductive layer 30 and the first thermally conductive lead frame 20, and the adhesive layer is made of a material selected from the group consisting of epoxy resin, silicone, acrylic resin, polyurethane, and a mixture or copolymer of combinations thereof. In an embodiment, the thermally conductive device 200 also includes an adhesive layer, identical to the aforementioned one, disposed between the electrically insulating but thermally conductive layer 30 and the second thermally conductive lead frame 40. In another embodiment, the metal compounds of the composite material do not act as fillers and can solely constitute the electrically insulating but thermally conductive layer 30, that is, the electrically insulating but thermally conductive layer 30 is made of the ceramic material selected from the group consisting of zirconium nitride, boron nitride, aluminum nitride, silicon nitride, aluminum oxide, magnesium oxide, zinc oxide, silicon dioxide, titanium dioxide, and any combination thereof.

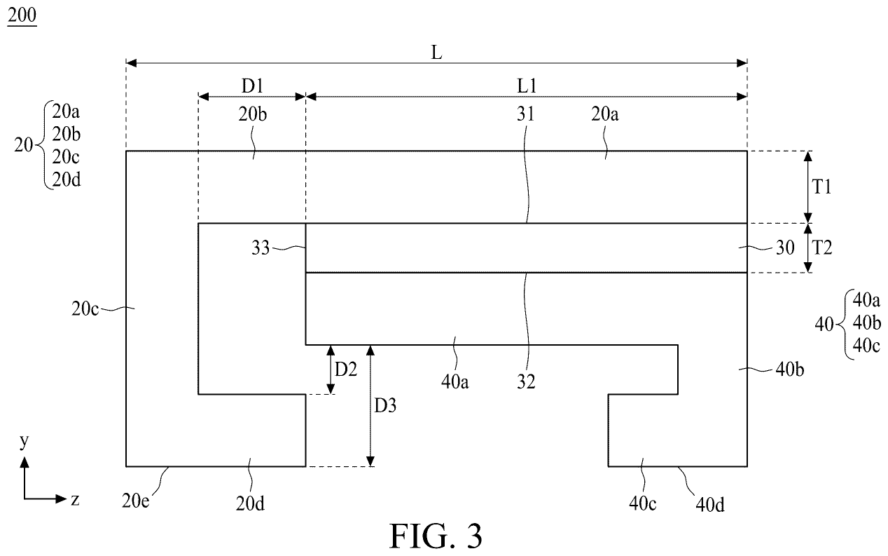

Please refer to FIG. 2 again. A substrate has two regions, a hot zone H and a cold zone C, respectively. The hot zone H is a region adjacent to a heat-generating device (e.g., a power device), and the temperature around it is relatively higher. The cold zone C is a region away from the heat-generating device, and the temperature around it is relatively lower. The lead of the first thermally conductive lead frame 20 can be welded to the hot zone H, while the lead of the second thermally conductive lead frame 40 can be welded to the cold zone C. This setup allows for rapid conduction of the heat accumulated around the heat-generating device from the hot zone H to the cold zone C, thereby reducing the temperature of the heat-generating device. It is understood that the cold region C may be any specified plane on the substrate, a region where a heat sink is located, a region where a thermally conductive film is located, or any other preset low-temperature regions. In an embodiment, the thermally conductive device 200 of the present invention has a length L ranging from 4 mm to 9 mm, a width W ranging from 1.5 mm to 6 mm, and a thickness T ranging from 1.5 mm to 3.5 mm. This structural design enlarges the cross-sectional area, which is perpendicular to the heat flow direction (i.e., y-axis). The cross-sectional area is substantially the top-view area of the electrically insulating but thermally conductive layer 30, ranging from 2 mm² to 40 mm², preferably from 13 mm² to 40 mm². In an embodiment, the top-view area of the electrically insulating but thermally conductive layer 30 may be 1.5 mm×1.5 mm, 1.8 mm×1.8 mm, 2.1 mm×2.1 mm, 4.5 mm×3.1 mm, 4 mm×4 mm, 5 mm×5 mm, or 6 mm×6 mm. For more specific details, please continuously refer to FIG. 3.

FIG. 3 shows a cross-sectional view of the thermally conductive device 200 along the line AA depicted in FIG. 2. The thermally conductive device 200 includes the electrically insulating but thermally conductive layer 30, the first thermally conductive lead frame 20, and the second thermally conductive lead frame 40. The electrically insulating but thermally conductive layer 30 has a top surface 31, a bottom surface 32, and a sidewall 33. The top surface 31 is opposite to the bottom surface 32, and the sidewall 33 connects to the top surface 31 and the bottom surface 32. The sidewall 33 is substantially perpendicular to the top surface 31 and the bottom surface 32. The first thermally conductive lead frame 20 has a top metal plate 20a, a first extending part 20b, and a second extending part 20c. The top metal plate 20a is disposed on the top surface 31 of the electrically insulating but thermally conductive layer 30. The first extending part 20b is parallel to the electrically insulating but thermally conductive layer 30, and extends from the top metal plate 20a and extends beyond the sidewall 33 along the z-axis. The second extending part 20c extends from the first extending part 20b and extends beyond the bottom surface 32 along the y-axis. The second thermally conductive lead frame 40 has a bottom metal plate 40a and a third extending part 40b. The bottom metal plate 40a is disposed on the bottom surface 32 of the electrically insulating but thermally conductive layer 30. The third extending part 40b extends from the bottom metal plate 40a and extends in a direction away from the electrically insulating but thermally conductive layer 30 along the y-axis. The space above the top surface 31 of the electrically insulating but thermally conductive layer 30 is defined as an upper side, while the space below the bottom surface 32 of the electrically insulating but thermally conductive layer 30 is defined as a lower side. Accordingly, the terminal of the second extending part 20c of the first thermally conductive lead frame 20 and the terminal of the third extending part 40b of the second thermally conductive lead frame 40 are on the same side, that is, the lower side. The first thermally conductive lead frame 20 has a first thickness T1 ranging from 0.3 mm to 0.7 mm, such as 0.3 mm, 0.4 mm, 0.5 mm, 0.6 mm, 0.7 mm. The second thermally conductive lead frame 40 has the same thickness as that of the first thermally conductive lead frame 20. The electrically insulating but thermally conductive layer 30 has a second thickness T2 ranging from 0.1 mm to 0.3 mm, such as 0.1 mm, 0.15 mm, 0.2 mm, 0.25 mm, or 0.3 mm. To increase the peel strength between the electrically insulating but thermally conductive layer 30 and the metal layers, a roughening process is performed on the top surface 31 and the bottom surface 32, thereby increasing the contact area between them and enhancing the effect of mechanical interlocking. A roughness (Ra) of the top surface 31 and the bottom surface 32 of the electrically insulating but thermally conductive layer 30 ranges from 0.01 μm to 10 μm. For the structural design of the thermally conductive lead frame of the present invention, the roughness (Ra) preferably ranges from 0.04 μm to 0.1 μm so as to provide sufficient peel strength.

It is noted that the first extending part 20b of the first thermally conductive lead frame 20 needs to extend a certain length to prevent the second extending part 20c from getting too close to the bottom metal plate 40a of the second thermally conductive lead frame 40. If the second extending part 20c of the first thermally conductive lead frame 20 is too close to, or even contacts, the bottom metal plate 40a of the second thermally conductive lead frame 40, it may lead to arcing during the operation of the thermally conductive device 200. Details are described hereinafter. The electrically insulating but thermally conductive layer 30 has a first length L1. The first extending part 20b extends beyond the sidewall 33 along the z-axis by a first distance D1. If the sum of the first length L1 and the first distance D1 are calculated as 100%, the first distance D1 ranges from 19% to 51%, such as 19%, 27%, 35%, 43%, or 51%. If the percentage of the first distance D1 is less than 19%, the second extending part 20c is too close to, or even contacts, the bottom metal plate 40a of the second thermally conductive lead frame 40, potentially causing arcing. If the percentage of the first distance D1 is more than 51%, the horizontal length of the first thermally conductive lead frame 20 becomes excessively long and does not meet the required specifications in the industry. In an embodiment, the first length L1 may be 1.5 mm, 1.8 mm, 2.1 mm, 3.1 mm, 4.5 mm, 5 mm, or 6 mm. For example, if the first length L1 is 1.5 mm, the first extending part 20b should extend beyond the sidewall 33 along the z-axis by the first distance D1 of at least 0.35 mm. If the first length L1 is 1.8 mm, the first extending part 20b should extend beyond the sidewall 33 along the z-axis by the first distance D1 of at least 0.42 mm. For conciseness, other first lengths L1 can be deduced in the same way without further elaboration. Furthermore, from the top-down perspective, the top-view area of the top metal plate 20a is the same as the top-view area of the electrically insulating but thermally conductive layer 30 of the first thermally conductive lead frame 20. The top metal plate 20a and the electrically insulating but thermally conductive layer 30 of the first thermally conductive lead frame 20 may have the same length and the width, and therefore the aforementioned first length L1 also represents the length of the top metal plate 20a. Similarly, the top-view area of the bottom metal plate 40a is the same as the top-view area of the electrically insulating but thermally conductive layer 30 of the second thermally conductive lead frame 40, and therefore the aforementioned first length L1 also represents the length of the bottom metal plate 40a.

For convenience of welding the thermally conductive device 200 to the substrate, the first thermally conductive lead frame 20 and the second thermally conductive lead frame 40 further include a first connecting terminal 20d and a second connecting terminal 40c, respectively. The first thermally conductive lead frame 20 includes the first connecting terminal 20d connected to the second extending part 20c, and the second thermally conductive lead frame 40 includes the second connecting terminal 40c connected to the third extending part 40b. The first connecting terminal 20d extends parallel to the bottom metal plate 40a toward the second connecting terminal 40c along the z-axis, and the second connecting terminal 40c extends parallel to the bottom metal plate 40a toward the first connecting terminal 20d along the z-axis. The first extending part 20b, the second extending part 20c, and the first connecting terminal 20d together form the lead of the first thermally conductive lead frame 20. The third extending part 40b and the second connecting terminal 40c together form the lead of the second thermally conductive lead frame 40. The first connecting terminal 20d of the first thermally conductive lead frame 20 is substantially coplanar with the second connecting terminal 40c of the second thermally conductive lead frame 40. The first connecting terminal 20d has a first bottom surface 20e, and the second connecting terminal 40c has a second bottom surface 40d. The first bottom surface 20e and the second bottom surface 40d are on the same horizontal plane (i.e., the xy-plane). In another embodiment, the first connecting terminal 20d and the second connecting terminal 40c extend in directions opposite to each other along the z-axis, by which the first connecting terminal 20d protrudes outward from the sidewall of the second extending part 20c (forming a reverse L-shape profile, not shown) and the second connecting terminal 40c protrudes outward from the sidewall of the third extending part 40b (forming an L-shape profile, not shown). If the first connecting terminal 20d of the first thermally conductive lead frame 20 adopts the design of the aforementioned “reverse L-shape” structure, it prevents the first connecting terminal 20d from getting too close to the bottom metal plate 40a of the second thermally conductive lead frame 40, thereby reducing the risk of arcing. Similarly, if the second connecting terminal 40c of the second thermally conductive lead frame 40 adopts the design of the aforementioned “L-shape” structure, it increases the distance between the second connecting terminal 40c and the first connecting terminal 20d, thereby reducing the likelihood of contact between the two terminals. For instance, if excessive amount of solder is accidentally applied to these two terminals, it ensures that a sufficient distance can be maintained between the solder on one terminal and the solder on the other terminal.

It is noted that the second extending part 20c of the first thermally conductive lead frame 20 needs to extend a certain length to prevent the first connecting terminal 20d from getting too close to the bottom metal plate 40a of the second thermally conductive lead frame 40. If the first connecting terminal 20d of the first thermally conductive lead frame 20 is too close to, or even contacts, the bottom metal plate 40a of the second thermally conductive lead frame 40, it may lead to arcing during the operation of the thermally conductive device 200. Therefore, the present invention raises the bottom metal plate 40a of the second thermally conductive lead frame 40 by a specific distance relative to the first connecting terminal 20d. The second extending part 20c extends beyond the bottom metal plate 40a by a second distance D2, and the bottom metal plate 40a is spaced apart from the horizontal plane by a third distance D3. If the third distance D3 is calculated as 100%, the second distance D2 ranges from 35% to 80%, such as 35%, 44%, 53%, 62%, 71%, or 80%. If the percentage of the second distance D2 is less than 35%, the first connecting terminal 20d is too close to, or even contacts, the bottom metal plate 40a of the second thermally conductive lead frame 40, potentially causing arcing. If the percentage of the second distance D2 is more than 80%, the bottom metal plate 40a is excessively raised and the device's size does not meet the required specifications in the industry. For example, in an embodiment, if the third distance D3 is 1.1 mm, the second distance D2 may range from 0.38 mm to 0.88 mm.

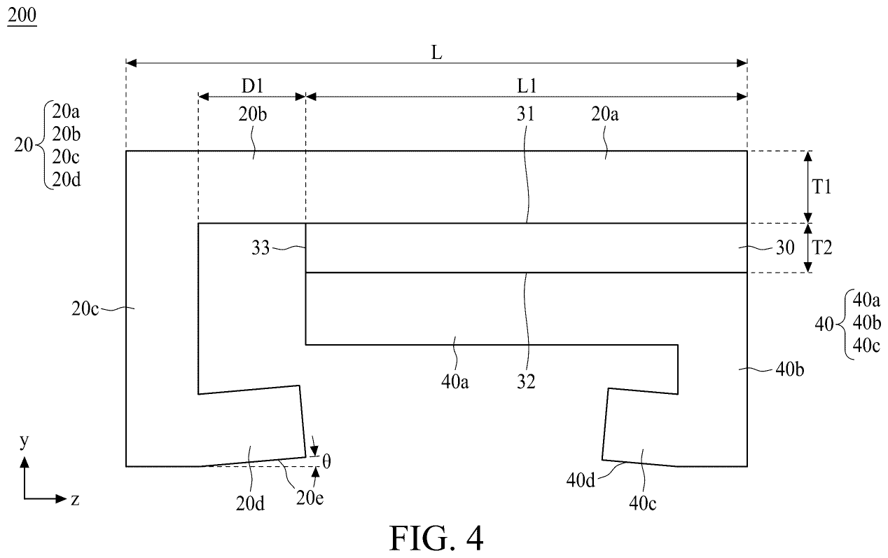

Please refer to FIG. 4. FIG. 4 shows an embodiment of the thermally conductive device 200 depicted in FIG. 3. The difference between FIG. 4 and FIG. 3 lies in the inclination of the terminal of the lead (i.e., the inclination of the first connecting terminal 20d or the second connecting terminal 40c). Besides that, the structural design and dimensions of the first thermally conductive lead frame 20, the second thermally conductive lead frame 40, and the electrically insulating but thermally conductive layer 30 in FIG. 4 are the same as previously described and not described in detail again. In FIG. 4, the first connecting terminal 20d of the first thermally conductive lead frame 20 extends toward the second connecting terminal 40c of the second thermally conductive lead frame 40, and likewise, the second connecting terminal 40c of the second thermally conductive lead frame 40 extends toward the first connecting terminal 20d of the first thermally conductive lead frame 20. An angle θ is formed between the first bottom surface 20e of the first connecting terminal 20d and the horizontal plane, and the angle θ is less than 30 degrees. On the basis of this design, more space is available for accommodating the solder beneath the first bottom surface 20e of the first connecting terminal 20d, which is beneficial for welding. It is noted that there is a limitation on the angle θ. If the angle θ is more than 30 degrees, the first connecting terminal 20d is too close to the bottom metal plate 40a, potentially causing arcing. Similarly, an angle (not shown) may be formed between the second bottom surface 40d of the second connecting terminal 40c and the horizontal plane. The inclined angle of the second connecting terminal 40c is the same as the inclined angle θ of the first connecting terminal 20d, and this symmetry in angle provides process convenience during punching. In an embodiment, the angle θ is 5 degrees, 10 degrees, 15 degrees, 20 degrees, 25 degrees, or 30 degrees. In a preferred embodiment, the angle θ is less than 10 degrees, thereby providing more tolerance to measurement error.

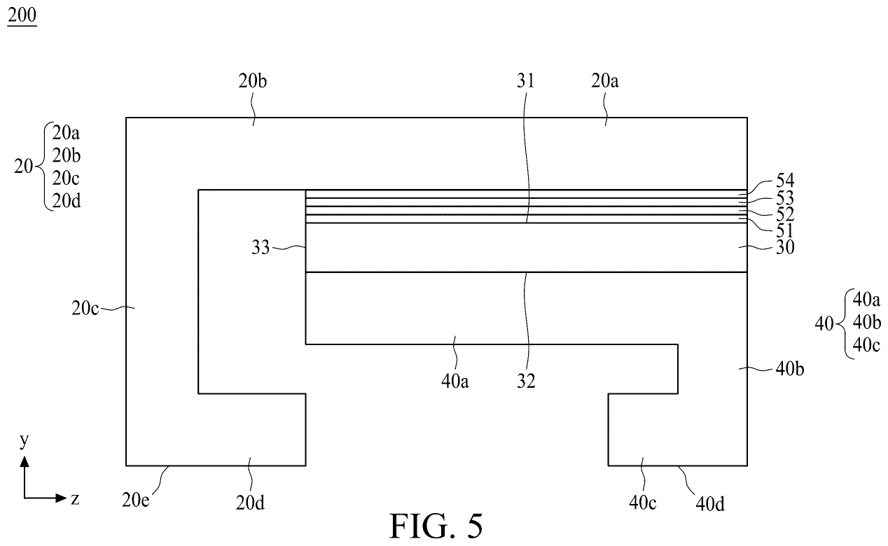

FIG. 5 shows another embodiment of the thermally conductive device 200 depicted in FIG. 3. The difference between FIG. 5 and FIG. 3 lies in additional layers between the metal plate and the electrically insulating layer. Besides that, the structural design and dimensions of the first thermally conductive lead frame 20, the second thermally conductive lead frame 40, and the electrically insulating but thermally conductive layer 30 in FIG. 5 are the same as previously described and not described in detail again. For ease of describing, certain reference numerals (e.g., L for length, L1 for first length, D1 for first distance, D2 for second distance, D3 for third distance, T1 for first thickness, and T2 for second thickness) are omitted herein. In FIG. 5, the thermally conductive device 200 further includes a first sputtering layer 51 and a second sputtering layer 52. By using a sputtering method, a first metal film (i.e., the first sputtering layer 51) can be formed on the surface of the electrically insulating but thermally conductive layer 30, thereby enhancing its adhesion to metal substrates. Considering the subsequent process of electroplating, a second metal film (i.e., the second sputtering layer 52) can be formed on the first sputtering layer 51 through the sputtering method. That is, the first sputtering layer 51 covers the top surface 31 of the electrically insulating but thermally conductive layer 30, and the second sputtering layer 52 covers the first sputtering layer 51. In an embodiment, the first sputtering layer 51 is made of titanium, zirconium, or tungsten. In an embodiment, the second sputtering layer 52 is made of copper or gold. It is noted that in order to reduce defects at the interface between the first sputtering layer 51 and the electrically insulating but thermally conductive layer 30, the difference in lattice constant between them should not be too large. For example, the first sputtering layer 51 has a first lattice constant, and the electrically insulating but thermally conductive layer 30 has a second lattice constant. Ideally, the optimal ratio of the first lattice constant to the second lattice constant is 1, meaning that the lattice constant of the first sputtering layer 51 completely matches the lattice constant of the electrically insulating but thermally conductive layer 30. In the present invention, a ratio of the first lattice constant to the second lattice constant may vary in a range from 0.9 to 1.2. In addition, the thicknesses between the first sputtering layer 51 and the second sputtering layer 52 need to be carefully controlled within a specific range. A ratio of the thickness of the first sputtering layer 51 to the thickness of the second sputtering layer 52 is in a range from 1:1 to 1:4, such as 1:1, 1:2, 1:3, or 1:4. Please refer to FIG. 5. The thermally conductive device 200 further includes a first electroplating layer 53 and a second electroplating layer 54. The first electroplating layer 53 covers the second sputtering layer 52, and the second electroplating layer 54 covers the first electroplating layer 53, by which the second electroplating layer 54 is able to be securely connected to the top metal plate 20a through solder. In an embodiment, the first electroplating layer 53 is made of nickel or copper. In an embodiment, the second electroplating layer 54 is made of tin.

Through the operation of electroplating, the top metal plate 20a of the first thermally conductive lead frame 20 can be welded to the electroplating layers so as to be assembled onto the top surface 31 of the electrically insulating but thermally conductive layer 30. Moreover, the thicknesses between the first electroplating layer 53 and the second electroplating layer 54 also need to be carefully controlled within a specific range. A ratio of the thickness of the first electroplating layer 53 to the thickness of the second electroplating layer 54 is in a range from 1:2 to 1:4, such as 1:2, 1:3, or 1:4. It is understood that the same design, as previously mentioned, can be applied to the layers between the bottom metal plate 40a of the second thermally conductive lead frame 40 and the bottom surface 32 of the electrically insulating but thermally conductive layer 30. That is, the thermally conductive device 200 may also include the sputtering layers and the electroplating layers laminated between the bottom metal plate 40a and the bottom surface 32. Similarly, the sputtering layers and the electroplating layers laminated between the bottom metal plate 40a and the bottom surface 32 may have the lattice-constant ratios and the thickness ratios as previously mentioned. Furthermore, the sputtering layers are not limited to two layers, nor are the electroplating layers. Additional metal layers can be further included between the first thermally conductive lead frame 20 (or the second thermally conductive lead frame 40) and the top surface 31 (or the bottom surface 32) in order to securely assemble the thermally conductive lead frames onto the electrically insulating but thermally conductive layer 30 or meet other requirements.

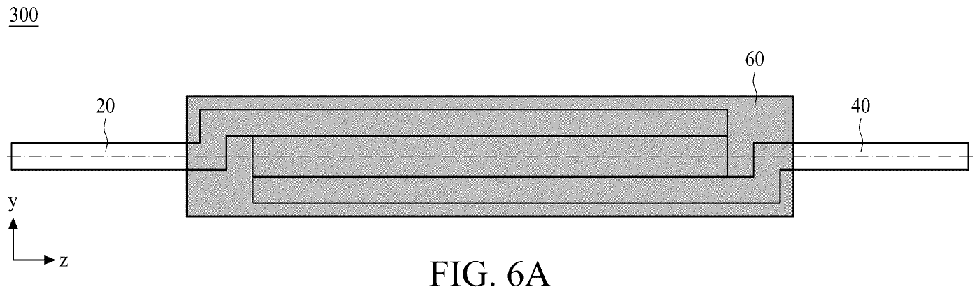

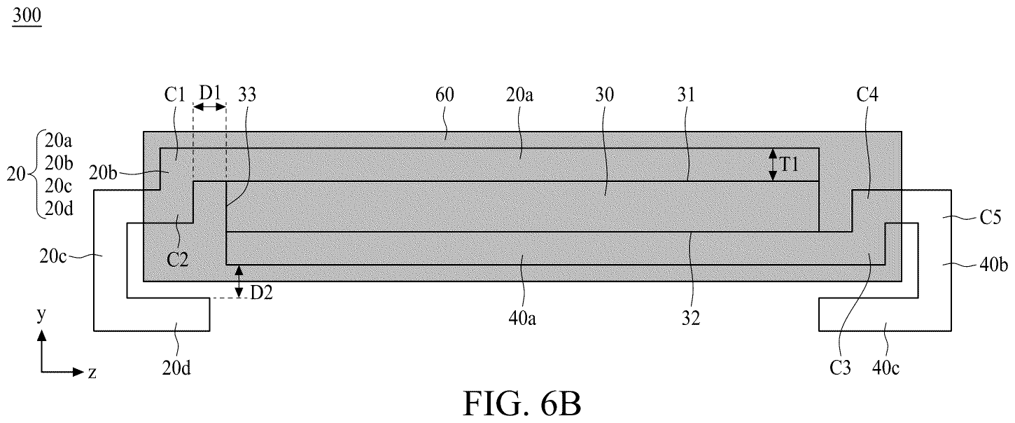

FIG. 6A and FIG. 6B show a thermally conductive device 300 after packaging. If the thermally conductive device needs to be packaged, slight variations in the manufacturing process may be necessary to conform to the standard equipment commonly used in the industry. For the thermally conductive device 200 without a packaging structure, the first thermally conductive lead frame 20 and the second thermally conductive lead frame 40 have been punched into the bending structures as shown in FIG. 3 beforehand, and then are assembled onto the top surface 31 and the bottom surface 32 of the electrically insulating but thermally conductive layer 30.

For the thermally conductive device 300 with a packaging structure, the first thermally conductive lead frame 20 and the second thermally conductive lead frame 40 are not punched into the bending structures (i.e., both of them are in the form of plate structures) at the beginning, and then these two plates are assembled onto the electrically insulating but thermally conductive layer. Then, as shown in FIG. 6A, the first thermally conductive lead frame 20 and the second thermally conductive lead frame 40 are slightly bent, and a packaging layer 60 packages the electrically insulating but thermally conductive layer, a part of the first thermally conductive lead frame 20, and a part of the second thermally conductive lead frame 40 through an injection molding operation. Afterward, a punching operation is performed to form the structure of the thermally conductive device 300 as shown in FIG. 6B. The aforementioned “slightly bent” is to make the central axis of the first thermally conductive lead frame 20 and the central axis of the second thermally conductive lead frame 40 align with the central axis of the electrically insulating but thermally conductive layer, as indicated by the dashed line shown in FIG. 6A. This alignment provides process convenience and the device can be punched into the final structure as shown in FIG. 6B. Actually, in terms of the final structure, the difference between the unpackaged thermally conductive device 200 and the packaged thermally conductive device 300 lies in the slightly bent portions (i.e., where the first extending part 20b and third extending part 40b are located). The details are described below. In FIG. 6B, the packaging layer 60 entirely covers the top metal plate 20a, the electrically insulating but thermally conductive layer 30, and the bottom metal plate 40a, and partially covers the first extending part 20b of the first thermally conductive lead frame 20 and the third extending part 40b of the second thermally conductive lead frame 40. The first extending part 20b of the first thermally conductive lead frame 20 has a first corner C1 and a second corner C2. The first extending part 20b extends to the first corner C1 in a direction parallel to the electrically insulating but thermally conductive layer 30 along the z-axis, extends from the first corner C1 to the second corner C2 in a direction parallel to the sidewall 33 along the y-axis, and then extends from the second corner C2 in a direction away from the sidewall 33 along the z-axis, thereby connecting to the second extending part 20c. The third extending part 40b of the second thermally conductive lead frame 40 has a third corner C3, a fourth corner C4, and a fifth corner C5. The third extending part 40b extends to the third corner C3 in a direction parallel to the electrically insulating but thermally conductive layer 30 along the z-axis, extends from the third corner C3 to the fourth corner C4 in a direction parallel to the sidewall 33 along the y-axis, extends from the fourth corner C4 to the fifth corner C5 in a direction away from the sidewall 33 along the z-axis, and then extends from the fifth corner C5 in a direction parallel to the sidewall 33 along the y-axis, thereby extending away from the electrically insulating but thermally conductive layer 30. After being packaged by the packaging layer 60, the breakdown voltage of the thermally conductive device 300 is significantly increased. For example, at dimensions of about 7 mm in length L, about 5 mm in width W, and about 2 mm in thickness T, the AC breakdown voltage of the thermally conductive device 200 in FIG. 3 exceeds 0.6 kV and its DC breakdown voltage exceeds 1 kV. However, at the same dimensions, the AC breakdown voltage of the thermally conductive device 300 in FIG. 6B exceeds 3.5 kV and its DC breakdown voltage exceeds 5 kV. It is noted that if the thermally conductive device is packaged, its thermally conductive lead frames can be designed to be thinner. For example, the first thickness

Tl of the first thermally conductive lead frame 20 of the thermally conductive device 300 may range from 0.1 mm to 0.25 mm, and so does the thickness of the second thermally conductive lead frame 40. Since the packaging layer 60 provides good electrical insulation, the second distance D2 maintained after punching the lead terminals (e.g., first connecting terminal 20d of the first thermally conductive lead frame 20) does not need to be carefully considered. During the punching operation, the surface of the packaging layer 60 may also serve as the stop surface where the first connecting terminal 20d and the second connecting terminal 40c abut against the packaging layer 60. That is, the first connecting terminal 20d and the second connecting terminal 40c extend toward each other so that the first connecting terminal 20d and the second connecting terminal 40c physically contact the packaging layer 60 (not shown). There are various designs for the above structure. The first connecting terminal 20d (or the second connecting terminal 40c) may be adhered parallel to the packaging layer 60, or extended at a specified angle (such as the angle 0 in FIG. 4) with only its end contacting the packaging layer 60. In one embodiment, the first connecting terminal 20d extends parallel to the bottom metal plate 40a toward the second connecting terminal 40c to contact the packaging layer 60, and the second connecting terminal 40c extends parallel to the bottom metal plate 40a toward the first connecting terminal 20d to contact the packaging layer 60. In another embodiment, the first connecting terminal 20d extends at a specified angle relative to the horizontal plane until it contacts the packaging layer 60, while the second connecting terminal 40c also extends at a specified angle relative to the horizontal plane until it contacts the packaging layer 60. It is noted that all the aforementioned designs related to the first thermally conductive lead frame 20, second thermally conductive lead frame 40, and the electrically insulating but thermally conductive layer 30 can also be applied to the thermally conductive device 300 in FIG. 6B.

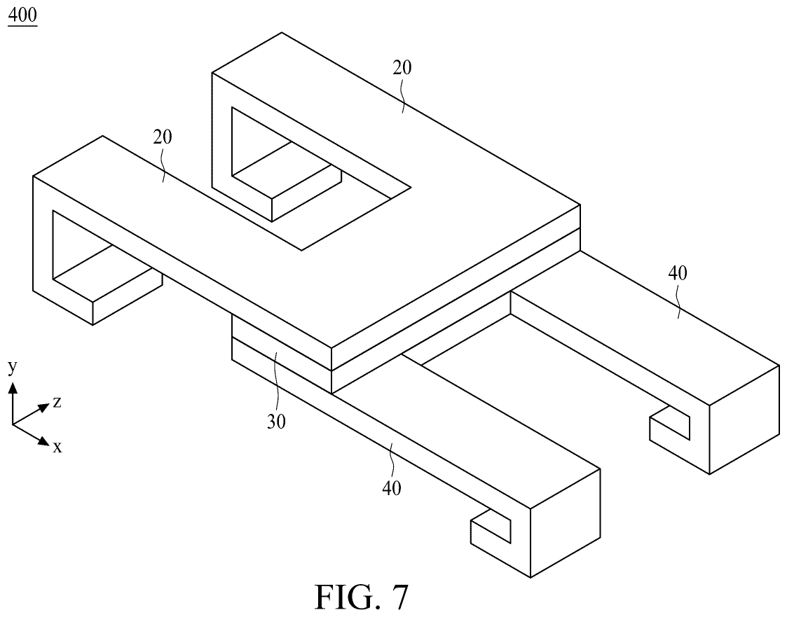

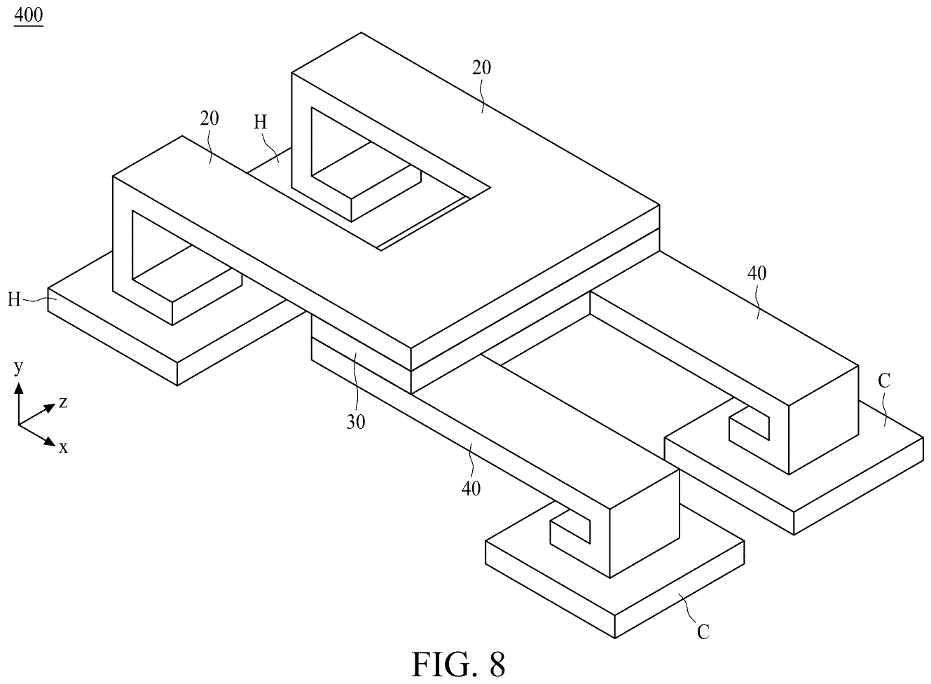

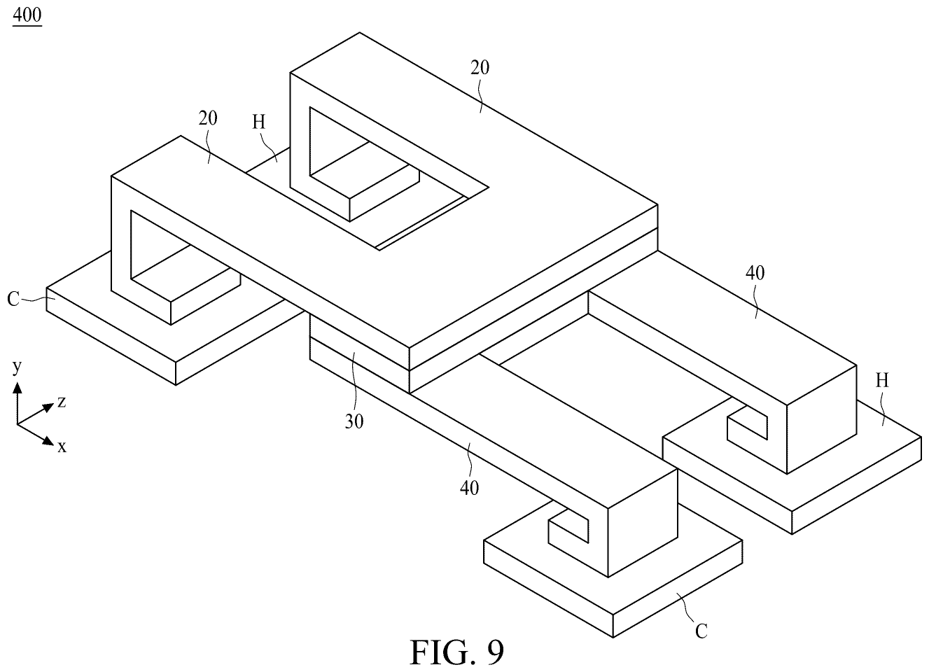

FIG. 7 to FIG. 9 show that a thermally conductive device 400 includes a plurality of the first thermally conductive lead frames 20 and a plurality of the second thermally conductive lead frames 40. For simplification and ease of understanding, only critical elements are indicated by reference numerals. To put it simply, a plurality of the thermally conductive lead frames may be derived from a single layer. In FIG. 7, the first thermally conductive lead frames 20 attach to the top surface of the electrically insulating but thermally conductive layer 30, and extend outward from one side of the thermally conductive device 400 along the x-axis. The second thermally conductive lead frames 40 attach to the bottom surface of the electrically insulating but thermally conductive layer 30, and extend outward from the opposite side of the thermally conductive device 400 along the x-axis. The top surface of the electrically insulating but thermally conductive layer 30 is opposite to the bottom surface of the electrically insulating but thermally conductive layer 30. Each first thermally conductive lead frame 20 and each second thermally conductive lead frame 40 extend in opposite directions along the x-axis. It is noted that in the thermally conductive device 400, the third extending part 40b of the second thermally conductive lead frame 40 is slightly modified. The third extending part 40b extends outward along the x-axis by a distance, and then extends in a direction away from the electrically insulating but thermally conductive layer 30. Alternatively, the second thermally conductive lead frame 40 in FIG. 7 may be designed to be identical to the second thermally conductive lead frame 40 in FIG. 3. This design (i.e., the structure of multiple leads extended from a single layer) not only offers flexibility in configuration but also enhances thermal conduction. For example, in FIG. 8, the substrate has two hot zones H and two cold zones C, and the thermally conductive device 400 has two first thermally conductive lead frames 20 and two second thermally conductive lead frames 40. All the first thermally conductive lead frames 20 may be welded to the hot zones H, while all the second thermally conductive lead frames 40 may be welded to the cold zones C. Alternatively, as depicted in the embodiment in FIG. 9, the opposing ones of the first thermally conductive lead frame 20 and the second thermally conductive lead frame 40 form a pair of lead frames, resulting in two pairs. One pair is welded to these two cold zones C, while the other pair is welded to these two hot zones H. It is noted that this structural design significantly increases the number of adjacent leads, and therefore the device may be packaged in order to prevent arcing. In an embodiment, the thermally conductive device 400 further includes the packaging layer 60 as previously mentioned.

The above-described embodiments of the present invention are intended to be illustrative only. Numerous alternative embodiments may be devised by persons skilled in the art without departing from the scope of the following claims.

1. A thermally conductive device, comprising:
an electrically insulating but thermally conductive layer having a top surface, a bottom surface, and a sidewall, wherein the top surface is opposite to the bottom surface, and the sidewall connects to the top surface and the bottom surface;
a first thermally conductive lead frame having a top metal plate, a first extending part, and a second extending part, wherein:
the top metal plate is disposed on the top surface;
the first extending part is parallel to the electrically insulating but thermally conductive layer, and extends from the top metal plate and beyond the sidewall; and
the second extending part extends from the first extending part and extends beyond the bottom surface; and
a second thermally conductive lead frame having a bottom metal plate and a third extending part, wherein:
the bottom metal plate is disposed on the bottom surface; and
the third extending part extends from the bottom metal plate and extends in a direction away from the electrically insulating but thermally conductive layer.

2. The thermally conductive device of claim 1, wherein:
the electrically insulating but thermally conductive layer has a length;
the first extending part extends beyond the sidewall by a first distance; and
if the sum of the length and the first distance are calculated as 100%, the first distance ranges from 19% to 51%.

3. The thermally conductive device of claim 1, wherein the first thermally conductive lead frame further comprises a first connecting terminal connected to the second extending part, and the second thermally conductive lead frame further comprises a second connecting terminal connected to the third extending part, wherein the first connecting terminal extends parallel to the bottom metal plate toward the second connecting terminal, and the second connecting terminal extends parallel to the bottom metal plate toward the first connecting terminal.

4. The thermally conductive device of claim 3, wherein:
the first connecting terminal has a first bottom surface, and the second connecting terminal has a second bottom surface, wherein the first bottom surface and the second bottom surface are on the same horizontal plane;
the second extending part extends beyond the bottom metal plate by a second distance, and the bottom metal plate is spaced apart from the horizontal plane by a third distance; and
if the third distance is calculated as 100%, the second distance ranges from 35% to 80%.

5. The thermally conductive device of claim 1, wherein:
the first thermally conductive lead frame further comprises a first connecting terminal connected to the second extending part, and the second thermally conductive lead frame further comprises a second connecting terminal connected to the third extending part, wherein the first connecting terminal and the second connecting terminal extend toward each other;
the first connecting terminal has a first bottom surface, and the second connecting terminal has a second bottom surface, wherein the first bottom surface and the second bottom surface are on the same horizontal plane; and
an angle is formed between the first bottom surface of the first connecting terminal and the horizontal plane, and the angle is less than 30 degrees.

6. The thermally conductive device of claim 5, wherein an angle is formed between the second bottom surface of the second connecting terminal and the horizontal plane, and the angle is less than 30 degrees.

7. The thermally conductive device of claim 1, further comprising a first sputtering layer and a second sputtering layer, wherein the first sputtering layer covers the top surface of the electrically insulating but thermally conductive layer, and the second sputtering layer covers the first sputtering layer.

8. The thermally conductive device of claim 7, wherein the first sputtering layer has a first lattice constant, and the electrically insulating but thermally conductive layer has a second lattice constant, wherein a ratio of the first lattice constant to the second lattice constant ranges from 0.9 to 1.2.

9. The thermally conductive device of claim 8, wherein a ratio of a thickness of the first sputtering layer to a thickness of the second sputtering layer is in a range from 1:1 to 1:4.

10. The thermally conductive device of claim 7, further comprising a first electroplating layer and a second electroplating layer, wherein the first electroplating layer covers the second sputtering layer, and the second electroplating layer covers the first electroplating layer, whereby the second electroplating layer is able to be securely connected to the top metal plate through solder.

11. The thermally conductive device of claim 10, wherein a ratio of a thickness of the first electroplating layer to a thickness of the second electroplating layer is in a range from 1:2 to 1:4.

12. The thermally conductive device of claim 1, further comprising a packaging layer, wherein the packaging layer entirely covers the top metal plate, the electrically insulating but thermally conductive layer, and the bottom metal plate, and wherein the packaging layer partially covers the first extending part and the third extending part.

13. The thermally conductive device of claim 12, wherein:
the first thermally conductive lead frame further comprises a first connecting terminal connected to the second extending part, and the second thermally conductive lead frame further comprises a second connecting terminal connected to the third extending part, wherein the first connecting terminal and the second connecting terminal extend toward each other; and
the first connecting terminal of the first thermally conductive lead frame physically contacts the packaging layer, and the second connecting terminal of the second thermally conductive lead frame physically contacts the packaging layer.

14. The thermally conductive device of claim 1, wherein:
the first extending part of the first thermally conductive lead frame has a first corner and a second corner, wherein the first extending part extends to the first corner in a direction parallel to the electrically insulating but thermally conductive layer, extends from the first corner to the second corner in a direction parallel to the sidewall, and then extends from the second corner in a direction away from the sidewall, thereby connecting to the second extending part; and
the third extending part of the second thermally conductive lead frame has a third corner, a fourth corner, and a fifth corner, wherein the third extending part extends to the third corner in a direction parallel to the electrically insulating but thermally conductive layer, extends from the third corner to the fourth corner in a direction parallel to the sidewall, extends from the fourth corner to the fifth corner in a direction away from the sidewall, and then extends from the fifth corner in a direction parallel to the sidewall, thereby extending away from the electrically insulating but thermally conductive layer.

15. The thermally conductive device of claim 14, further comprising a packaging layer, wherein the packaging layer entirely covers the top metal plate, the electrically insulating but thermally conductive layer, and the bottom metal plate, and wherein the packaging layer partially covers the first extending part and the third extending part.

16. The thermally conductive device of claim 15, wherein:
the first thermally conductive lead frame further comprises a first connecting terminal connected to the second extending part, and the second thermally conductive lead frame further comprises a second connecting terminal connected to the third extending part, wherein the first connecting terminal and the second connecting terminal extend toward each other; and
the first connecting terminal of the first thermally conductive lead frame physically contacts the packaging layer, and the second connecting terminal of the second thermally conductive lead frame physically contacts the packaging layer.

17. The thermally conductive device of claim 14, wherein a thickness of the first thermally conductive lead frame ranges from 0.1 mm to 0.25 mm.

18. The thermally conductive device of claim 1, wherein the thermally conductive device comprises a plurality of the first thermally conductive lead frames and a plurality of the second thermally conductive lead frames.

19. The thermally conductive device of claim 1, wherein the first thermally conductive lead frame and the second thermally conductive lead frame are made of copper or copper alloy.

20. The thermally conductive device of claim 1, further comprising an adhesive layer disposed between the electrically insulating but thermally conductive layer and the first thermally conductive lead frame, wherein the adhesive layer is made of a material selected from the group consisting of epoxy resin, silicone, acrylic resin, polyurethane, and a mixture or copolymer of combinations thereof.

21. The thermally conductive device of claim 1, wherein the electrically insulating but thermally conductive layer is made of epoxy resin and a thermally conductive filler, wherein the thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof.

22. The thermally conductive device of claim 1, wherein the electrically insulating but thermally conductive layer is made of a ceramic material, wherein the ceramic material is selected from the group consisting of zirconium nitride, boron nitride, aluminum nitride, silicon nitride, aluminum oxide, magnesium oxide, zinc oxide, silicon dioxide, titanium dioxide, and any combination thereof.

23. The thermally conductive device of claim 21, wherein a roughness (Ra) of the top surface and the bottom surface of the electrically insulating but thermally conductive layer ranges from 0.01 μm to 10 μm.
